(19) United States
(12) Patent Application Publication
(10) Pub. No.: US 2025/0311201 A1
(43) Pub. Date: Oct. 2, 2025

(54) SEMICONDUCTOR DEVICE AND METHOD FOR FABRICATING THE SAME

(71) Applicant: SK hynix Inc., Gyeonggi-do (KR)

(72) Inventors: Kyung Sun RYU, Gyeonggi-do (KR); Beomyoung KIM, Gyeonggi-do (KR); Jaesuk CHOI, Gyeonggi-do (KR)

(21) Appl. No.: 18/987,385

(22) Filed: Dec. 19, 2024

(30) Foreign Application Priority Data
Apr. 1, 2024 (KR) 10-2024-0044043

(51) Int. Cl. H10B 12/00

(52) U.S. Cl. CPC H10B 12/485; H10B 12/0335; H10B 12/053; H10B 12/315; H10B 12/34

(57) ABSTRACT

A method for fabricating a semiconductor device includes forming a plurality of line structures and line-shaped openings between the line structures, over a substrate; filling the line-shaped openings with conductive line patterns, respectively; forming a plurality of plugs and a plurality of isolation openings by etching the conductive line patterns; forming air gap target layers in the isolation openings, respectively; forming liner layers over the air gap target layers, respectively; and replacing the air gap target layers with air gaps.

### CROSS-REFERENCE TO RELATED APPLICATIONS

The present application claims priority under 35 U.S.C 119(a) to Korean Patent Application No. 10-2024-0044043, filed on Apr. 1, 2024, which is incorporated herein by reference in its entirety.

### BACKGROUND

### 1. Field

Embodiments of the present invention relate to a semiconductor device, and more particularly, to a semiconductor device including an air gap, and a method for fabricating the semiconductor device.

### 2. Description of the Related Art

In semiconductor devices, dielectric materials are formed between the neighboring pattern structures. As semiconductor devices become more highly integrated, the distance between the pattern structures is getting closer, which may increase parasitic capacitance. As the parasitic capacitance increases, the performance of the semiconductor device is deteriorated.

### SUMMARY

Embodiments of the present invention are directed to a semiconductor device with improved reliability, and a method for fabricating the semiconductor device.

In accordance with an embodiment of the present invention, a semiconductor device includes a plurality of line structures including a plurality of first conductive patterns over a substrate, respectively; a plurality of second conductive patterns formed between the line structures, respectively; a plurality of isolation layers formed between the line structures and the second conductive patterns, respectively; and a plurality of air gaps disposed at a lower level than the isolation layers to be disposed between the second conductive patterns, respectively.

In accordance with another embodiment of the present invention, a method for fabricating a semiconductor device includes forming a plurality of line structures and line-shaped openings between the line structures, over a substrate; filling the line-shaped openings with conductive line patterns, respectively; forming a plurality of plugs and a plurality of isolation openings by etching the conductive line patterns; forming air gap target layers in the isolation openings, respectively; forming liner layers over the air gap target layers, respectively; and replacing the air gap target layers with air gaps.

In accordance with another embodiment of the present invention, a method for fabricating a semiconductor device includes forming a plurality of bit line structures over a substrate; forming line-shaped openings between the bit line structures, respectively; filling the line-shaped openings with conductive line patterns, respectively; forming a plurality of storage contact plugs and a plurality of isolation openings between the storage contact plugs by etching the conductive line patterns; filling a pyrolytic material in each of the isolation openings to form air gap target layers; forming a liner layer over the air gap target layers; replacing the air gap target layers with air gaps; and forming a gap-fill layer over the liner layer.

### BRIEF DESCRIPTION OF THE DRAWINGS

FIG. 1 is a plan view illustrating a semiconductor device in accordance with an embodiment of the present invention.

FIG. 2A is a cross-sectional view taken along a line A-A′ shown in FIG. 1.

FIG. 2B is a cross-sectional view taken along a line B-B′ shown in FIG. 1.

FIG. 2C is a cross-sectional view taken along a line C-C′ shown in FIG. 1.

FIGS. 3A, 4A, 5A, 6A, 7A, 8A, 9A, 10A, 11A, 12A, 13A and 14A are plan views illustrating a method for fabricating semiconductor devices in accordance with embodiments of the present invention.

FIGS. 3B, 4B, 5B, 6B, 7B, 8B, 9B, 10B, 11B, 12B, 13B and 14B are cross-sectional views taken along lines A-A′ and B-B′ shown in FIGS. 3A, 4A, 5A, 6A, 7A, 8A, 9A, 10A, 11A, 12A, 13A and 14A.

### DETAILED DESCRIPTION

Embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout this disclosure, like reference numerals refer to like parts throughout the various figures and embodiments of the present invention. The drawings are not necessarily to scale and in some instances, proportions may have been exaggerated in order to clearly illustrate features of the embodiments. When a first layer is referred to as being ‘on’ a second layer or ‘on’ a substrate, it not only refers to a case where the first layer is formed directly on the second layer or the substrate but also a case where a third layer exists between the first layer and the second layer or the substrate.

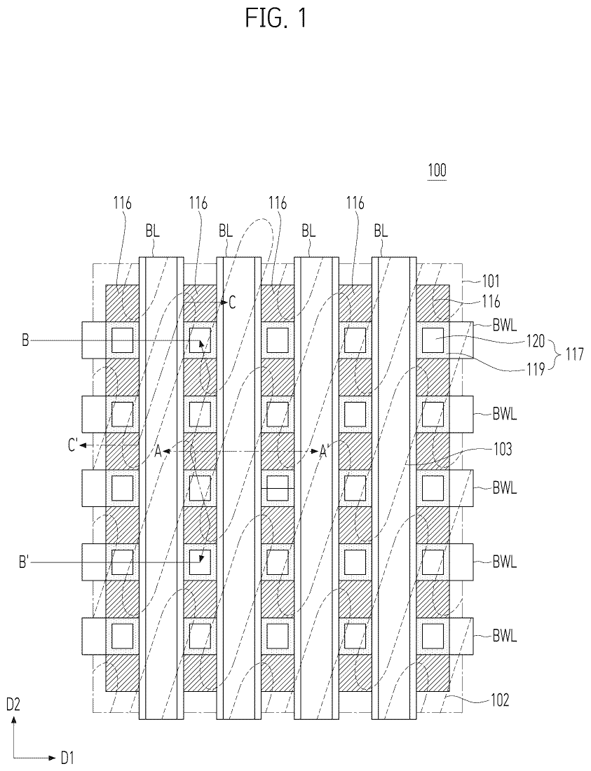

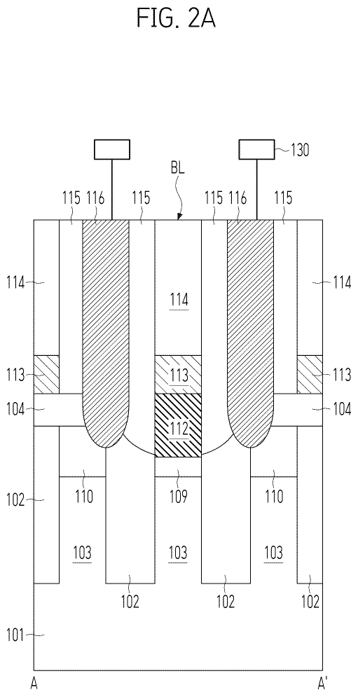

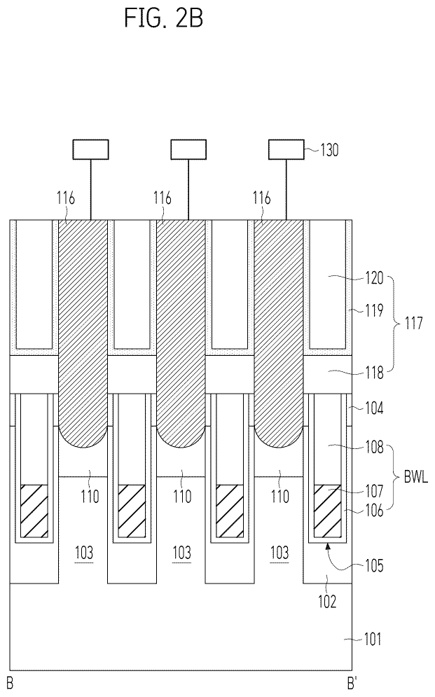

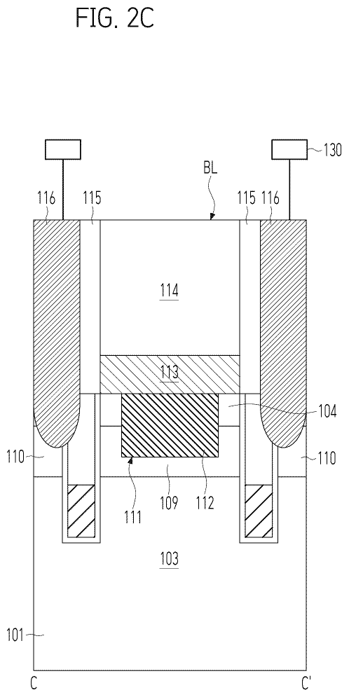

FIG. 1 is a plan view illustrating a semiconductor device 100 in accordance with an embodiment of the present invention. FIG. 2A is a cross-sectional view taken along a line A-A′ shown in FIG. 1. FIG. 2B is a cross-sectional view taken along a line B-B′ shown in FIG. 1. FIG. 2C is a cross-sectional view taken along a line C-C′ shown in FIG. 1.

Referring to FIGS. 1 to 2C, the semiconductor device 100 may include a plurality of line structures (e.g., bit line structures) BL including a plurality of first conductive patterns 113 over a substrate 101, a plurality of second conductive patterns 116 formed between the line structures BL, respectively, a plurality of isolation layers 117 formed between the line structures BL and the second conductive patterns 116, respectively, and a plurality of air gaps 118 disposed at a lower level than the isolation layers 117 to be arranged between the second conductive patterns 116, respectively. The first conductive pattern 113 may include a bit line 113, and the line structure BL may include a bit line structure BL. The second conductive patterns 116 may include storage contact plugs. The isolation layers 117 may include a plug isolation structure.

The semiconductor device 100 may include a plurality of memory cells. Each memory cell may include a cell transistor including a buried word line structure BWL, and a bit line 113.

An isolation layer 102 and an active region 103 may be formed in the substrate 101. In the illustrated example, a plurality of active regions 103 may be defined by a plurality of isolation layers 102. The substrate 101 may be a material appropriate for semiconductor processing. The substrate 101 may include a semiconductor substrate. The substrate 101 may be formed of a material containing silicon. The substrate 101 may include silicon, single crystalline silicon, polysilicon, amorphous silicon, silicon germanium, single crystalline silicon germanium, polycrystalline silicon germanium, carbon-doped silicon, a combination thereof, or a multi-layer thereof. The substrate 101 may also include other semiconductor materials, such as germanium. The substrate 101 may include a III-V group semiconductor substrate, for example, a compound semiconductor substrate, such as gallium arsenide (GaAs). The substrate 101 may also include a Silicon-On-Insulator (SOI) substrate. The isolation layer 102 may be formed by a Shallow Trench Isolation (STI) process.

A gate trench 105 may be formed in the substrate 101. A buried word line structure BWL may be formed in the gate trench 105. The buried word line structure BWL may include a gate dielectric layer 106, a buried word line 107, and a gate capping layer 108. The gate dielectric layer 106 may be formed on an inner surface of the gate trench 105. A buried word line 107 may be formed over the gate dielectric layer 106 to fill a portion (e.g., a lower portion) of the gate trench 105. The gate capping layer 108 may be formed over the buried word line 107. The top surface of the buried word line 107 may be disposed at a lower level than the top surface of the substrate 101. The buried word line 107 may include a low-resistance metal material. The buried word line 107 may be formed by sequentially stacking titanium nitride and tungsten. According to another embodiment of the present invention, the buried word line 107 may be formed of titanium nitride only (TiN Only). The buried word line 107 may be referred to as a ‘buried gate electrode’. The buried word line 107 may extend in a first direction D1.

First and second impurity regions 109 and 110 may be formed over the substrate 101. The first and second impurity regions 109 and 110 may be separated from each other by the gate trench 105. The first and second impurity regions 109 and 110 may be referred to as source/drain regions. The first and second impurity regions 109 and 110 may include an N-type impurity, such as arsenic (As) or phosphorus (P). The buried word line 107 and the first and second impurity regions 109 and 110 may become a cell transistor. The cell transistor may improve the short channel effect by the buried word line 107.

A bit line contact plug 112 may be formed over the substrate 101. The bit line contact plug 112 may be coupled to the first impurity region 109. The bit line contact plug 112 may be disposed in the bit line contact hole 111. The bit line contact hole 111 may extend to the substrate 101 through the hard mask layer 104. The hard mask layer 104 may be formed over the substrate 101. The hard mask layer 104 may include a dielectric material. The bit line contact hole 111 may expose the first impurity region 109. The bottom surface of the bit line contact plug 112 may be lower than the top surfaces of the isolation layer 102 and the active region 103, as shown in FIG. 2A. The bit line contact plug 112 may be formed of polysilicon or a metal material. A portion of the bit line contact plug 112 may have a line width which is less than the diameter of the bit line contact hole 111. A bit line 113 may be formed over the bit line contact plug 112. A bit line hard mask 114 may be formed over the bit line 113. A stacked structure of the bit line contact plug 112, the bit line 113, and the bit line hard mask 114 may be referred to as a bit line structure BL. The bit line 113 may have a line shape extending in a second direction D2 intersecting with the buried word line 107. A portion of the bit line 113 may be coupled to the bit line contact plug 112. The bit line 113 and the bit line contact plug 112 in the first direction D1 may have the same line width. Therefore, the bit line 113 may extend in the second direction D2 while covering the bit line contact plug 112. The bit line 113 may include a metal material, such as tungsten. The bit line hard mask 114 may include a dielectric material, such as silicon nitride.

A spacer structure 115 may be formed on a side wall of the bit line structure BL. The spacer structure 115 may extend to be disposed on a side wall of the bit line contact plug 112. The spacer structure 115 may include silicon nitride, silicon oxide, a low-k material, or a combination thereof. The low-k material may have a lower dielectric constant than that of silicon nitride. The low-k material may include SiBN, SiCO, SiCN, SiBCN, or a combination thereof. According to another embodiment of the present invention, the spacer structure 115 may include a multi-layer spacer. For example, the spacer structure 115 may include NKON, NKNAN, NKOK, NKOKN, NKAKN, KOK, or KAK, where N refers to silicon nitride, and K refers to a low-k material, and O refers to silicon oxide, and A refers According to another embodiment of the present to an air gap. invention, the outermost spacer of the spacer structure 115 may include a low-k material.

The storage contact plug 116 may be formed between the neighboring bit line structures BL. The storage contact plug 116 may be coupled to the second impurity region 110. The storage contact plug 116 may include polysilicon, a metal nitride, a metal material, a metal silicide, or a combination thereof. According to some embodiments of the present invention, the storage contact plug 116 may include polysilicon, cobalt silicide, and tungsten that are stacked in the mentioned order.

A plug isolation structure 117 may be formed between the neighboring storage contact plugs 116 from the perspective of a direction parallel to the bit line structure BL. The plug isolation structure 117 may be formed between the neighboring bit line structures BL. The neighboring storage contact plugs 116 may be separated in the second direction D2 by two adjacent plug isolation structures 117. The plug isolation structures 117 may be referred to as inter-plug dielectric layers. Between the neighboring bit line structures BL, a plurality of plug isolation structures 117 and a plurality of storage contact plugs 116 may be alternately disposed in the second direction D2. The storage contact plugs 116 may directly contact the spacer structure 115.

A memory element 130 may be formed over the storage contact plug 116. The memory element 130 may include a capacitor including a storage node. The storage node may have a pillar shape. In some embodiments, a dielectric layer and a plate node may be further formed over the storage node. Alternatively, the storage node may have a cylinder shape.

The plug isolation structure 117 may be referred to as an isolation layer or a pattern isolation layer. The plug isolation structure 117 may include an air gap, silicon nitride, a low-k material, or a combination thereof. When the plug isolation structure 117 includes a low-k material, the parasitic capacitance between the neighboring storage contact plugs 116 with the plug isolation structure 117 interposed therebetween may be decreased. The plug isolation structure 117 may include an air gap, SiCO, SiCN, SiOCN, SiBN, SiBCN, or a combination thereof.

In the illustrated embodiment of FIG. 2B, the plug isolation structure 117 may include a combination of an air gap 118, a liner layer 119, and a gap-fill layer 120. Each of the liner layer 119 and the gap-fill layer 120 may include a nitride. The liner layer 119 may include a low temperature nitride. The air gap 118 may directly contact the lower side wall of the storage contact plug 116. The air gap 118 may be disposed between the lower side walls of the neighboring storage contact plugs 116. The liner layer 119 and the gap-fill layer 120 may be referred to as a ‘plug isolation layer’, and the air gap 118 may be disposed at a lower level than The liner layer 119 and the gap-fill layer 120 to be arranged between the storage contact plugs 116.

As shown in FIGS. 1 to 2C, the semiconductor device 100 may include storage contact plugs 116 disposed between the bit line structures BL, and plug isolation structures 117 disposed between the bit line structures BL and the storage contact plugs 116. Each of the plug isolation structures 117 may include the air gap 118.

Since the air gap 118 is formed between the storage contact plugs 116, leakage current may be decreased. Also, since the air gap 118 is formed between the storage contact plugs 116, the parasitic capacitance between the storage contact plugs 116 may be decreased.

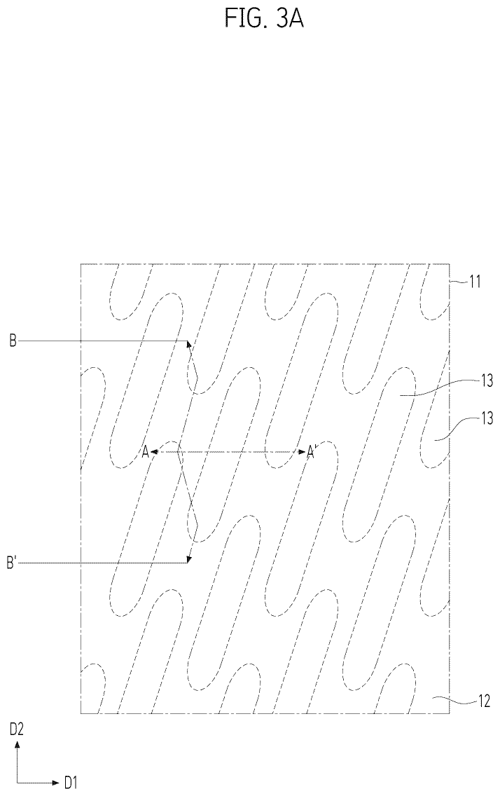

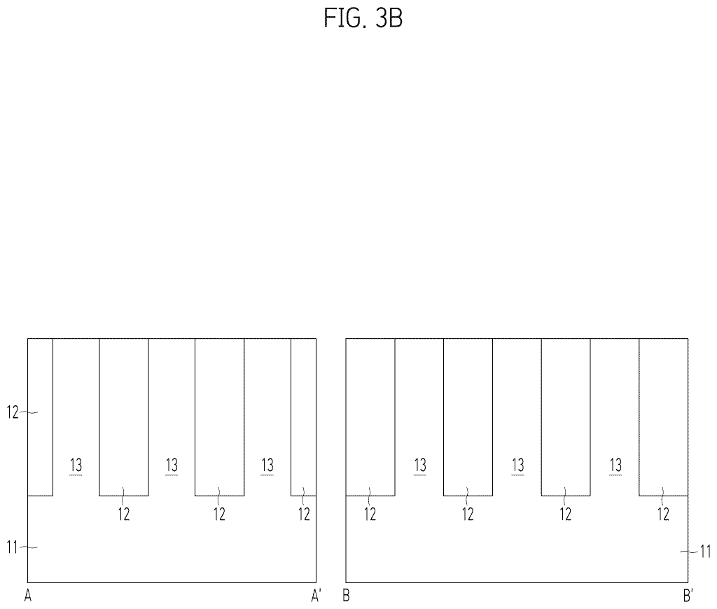

FIGS. 3A to 14B illustrate a method for fabricating a semiconductor device in accordance with embodiments of the present invention. FIGS. 3A, 4A, 5A, 6A, 7A, 8A, 9A, 10A, 11A, 12A, 13A and 14A are plan views illustrating a method for fabricating a semiconductor device in accordance with the embodiments of the present invention. FIGS. 3B, 4B, 5B, 6B, 7B, 8B, 9B, 10B, 11B, 12B, 13B and 14B are cross-sectional views taken along the lines A-A′ and B-B′ shown in FIGS. 3A, 4A, 5A, 6A, 7A, 8A, 9A, 10A, 11A, 12A, 13A and 14A.

Referring to FIGS. 3A and 3B, an isolation layer 12 may be formed in a substrate 11. A plurality of active regions 13 may be defined in the substrate 11 by the isolation layer 12. The isolation layer 12 may be formed by a Shallow Trench Isolation (STI) process. The shallow trench isolation process may be performed as follows. An isolation trench (whose reference symbol is omitted) may be formed by etching the substrate 11. The isolation trench may be filled with a dielectric material, and as a result, the isolation layer 12 may be formed. The isolation layer 12 may include silicon oxide, silicon nitride, or a combination thereof. A Chemical Vapor Deposition (CVD) process or other deposition processes may be performed to fill the isolation trench with the dielectric material. A planarization process, such as Chemical-Mechanical Polishing (CMP), may be additionally performed.

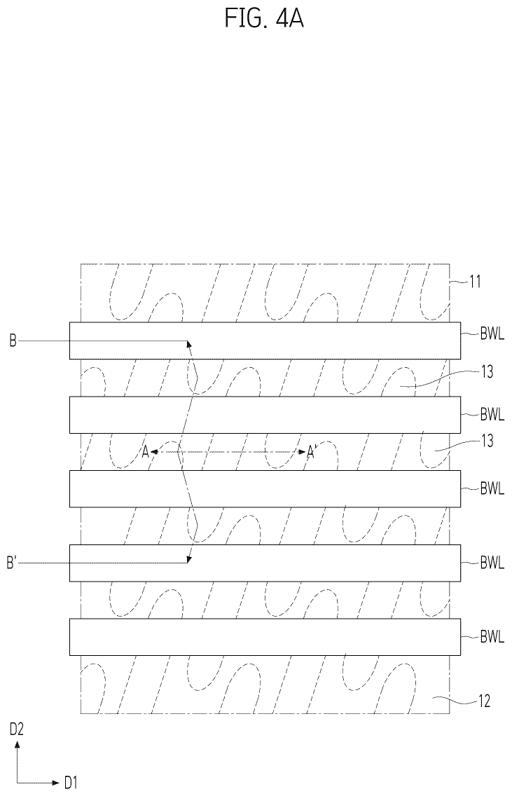

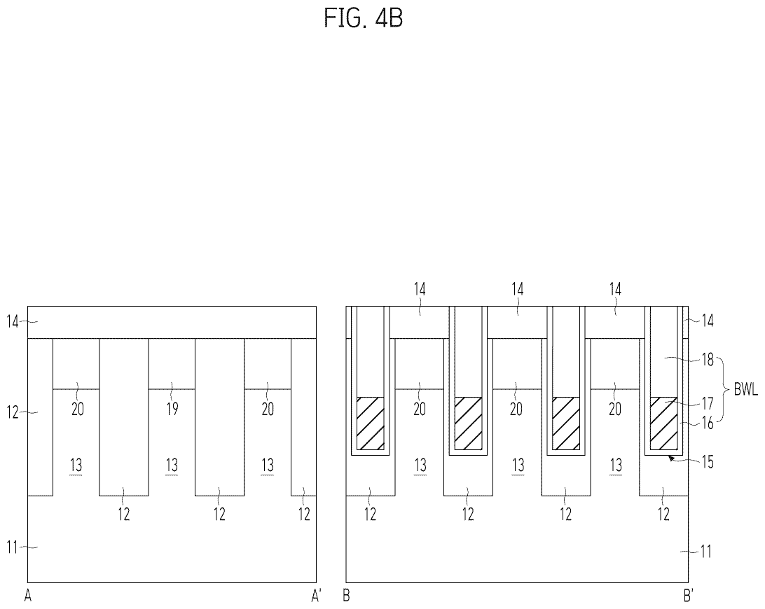

Referring to FIGS. 4A and 4B, a gate trench 15 may be formed in the substrate 11. A buried word line structure BWL may be formed in the gate trench 15. The buried word line structure BWL may include a gate dielectric layer 16 covering the bottom surface and side walls of the gate trench 15, a buried word line 17 filling a portion of the gate trench 15 over the gate dielectric layer 16, and a gate capping layer 18 formed over the buried word line 17.

A method of forming the buried word line structure BWL is described as follows.

First, the gate trench 15 may be formed in the substrate 11. The gate trench 15 may have a line shape intersecting with the active regions 13 and the isolation layer 12. The gate trench 15 may be formed by forming a mask pattern over the substrate 11 and performing an etching process using the mask pattern as an etching mask. To form the gate trench 15, a hard mask layer 14 may be used as an etching barrier. The hard mask layer 14 may have a shape that is patterned by the mask pattern. The hard mask layer 14 may include silicon oxide. The hard mask layer 14 may include Tetraethyl orthosilicate (TEOS). The bottom surface of the gate trench 15 may be disposed at a higher level than the bottom surface of the isolation layer 12.

In some embodiments, a portion of the isolation layer 12 may be recessed to protrude the active region 13 below the gate trench 15. For example, the isolation layer 12 below the gate trench 15 may be selectively recessed in the longitudinal direction of the gate trench 15. As a result, a fin region may be formed below the gate trench 15. The fin region may be a portion of a channel region.

Subsequently, the gate dielectric layer 16 may be formed on the bottom surface and side walls of the gate trench 15. Before the gate dielectric layer 16 is formed, etching damage on the surface of the gate trench 15 may be cured. For example, after a sacrificial oxide is formed by a thermal oxidation process, the sacrificial oxide may be removed.

The gate dielectric layer 16 may be formed by a thermal oxidation process. For example, the bottom and side walls of the gate trench 15 may be oxidized to form the gate dielectric layer 16.

According to another embodiment of the present invention, the gate dielectric layer 16 may be formed by a deposition method, such as a Chemical Vapor Deposition (CVD) process or an Atomic Layer Deposition (ALD) process. The gate dielectric layer 16 may include a high-k material, an oxide, a nitride, an oxynitride, or a combination thereof. The high-k material may include a hafnium-containing material. The hafnium-containing material may include hafnium oxide, hafnium silicon oxide, hafnium silicon oxynitride, or a combination thereof. According to another embodiment of the present invention, the high-k material may include lanthanum oxide, lanthanum aluminum oxide, zirconium oxide, zirconium silicon oxide, zirconium silicon oxynitride, aluminum oxide, or a combination thereof.

According to another embodiment of the present invention, the gate dielectric layer 16 may be formed by depositing a liner polysilicon layer and then radically oxidizing the liner polysilicon layer.

According to yet another embodiment of the present invention, the gate dielectric layer 16 may be formed by forming a liner silicon nitride layer and then radically oxidizing the liner silicon nitride layer.

Subsequently, the buried word line 17 may be formed over the gate dielectric layer 16. To form the buried word line 17, a conductive layer may be formed to fill the gate trench 15, and then a recessing process may be performed. The recessing process may be performed by an etch-back process, or by a Chemical-Mechanical Polishing (CMP) process and an etch-back process that are sequentially performed. The buried word line 17 may have a recessed shape that fills a portion of the gate trench 15. The top surface of the buried word line 17 may be disposed at a lower level than the top surface of the active region 13. The buried word line 17 may include a semiconductor material, a metal, a metal nitride, or a combination thereof. For example, the buried word line 17 may be formed of titanium nitride (TiN), tungsten (W), or a titanium nitride/tungsten (TiN/W) stack. The titanium nitride/tungsten (TiN/W) stack may be a structure in which titanium nitride is conformally formed and then a portion of the gate trench 15 is filled with tungsten. Titanium nitride may be used alone as the buried word line 17, which may be referred to as a buried word line 17 of a ‘TiN Only’ structure. A double gate structure of a titanium nitride/tungsten (TiN/W) stack and a polysilicon layer may also be used as the buried word line 17.

Subsequently, the gate capping layer 18 may be formed over the buried word line 17. The gate capping layer 18 may include a dielectric material. The remaining portion of the gate trench 15 may be filled with the gate capping layer 18 over the buried word line 17. The gate capping layer 18 may include silicon nitride. According to another embodiment of the present invention, the gate capping layer 18 may include silicon oxide. According to yet another embodiment of the present invention, the gate capping layer 18 may have a Nitride-Oxide-Nitride (NON) structure. The top surface of the gate capping layer 18 may be disposed at the same level as the top surface of the hard mask layer 14. To this end, a Chemical-Mechanical Polishing (CMP) process may be performed when the gate capping layer 18 is formed.

After the gate capping layer 18 is formed, impurity regions 19 and 20 may be formed. The impurity regions 19 and 20 may be formed by a doping process such as an implantation process. The impurity regions 19 and 20 may include a first impurity region 19 and a second impurity region 20. The first and second impurity regions 19 and 20 may be doped with impurities of the same conductivity type. The first and second impurity regions 19 and 20 may have the same depth. According to another embodiment of the present invention, the first impurity region 19 may be deeper than the second impurity region 20. The first and second impurity regions 19 and 20 may be referred to as source/drain regions. The first impurity region 19 may be a region to which a bit line contact plug is to be coupled, whereas the second impurity region 20 may be a region to which a storage contact plug is to be coupled. The first impurity region 19 and the second impurity region 20 may be disposed in different active regions 13. Also, the first impurity region 19 and the second impurity region 20 may be disposed in the respective active regions 13 to be spaced apart from each other by the gate trenches 15.

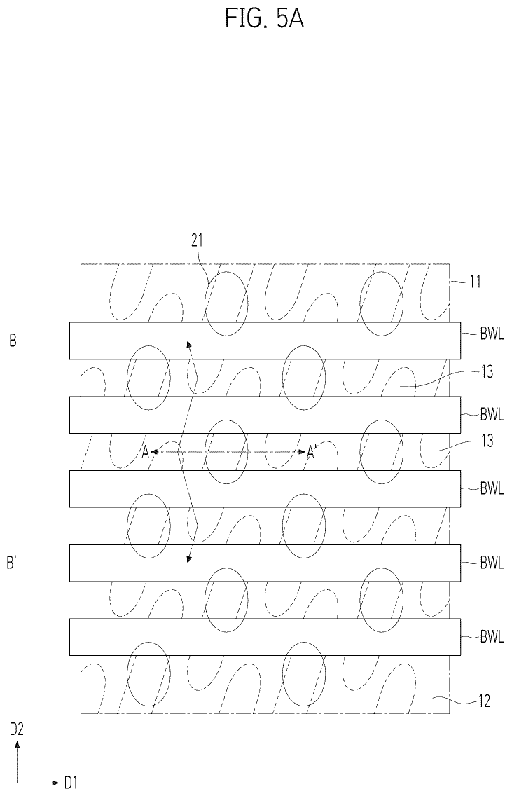

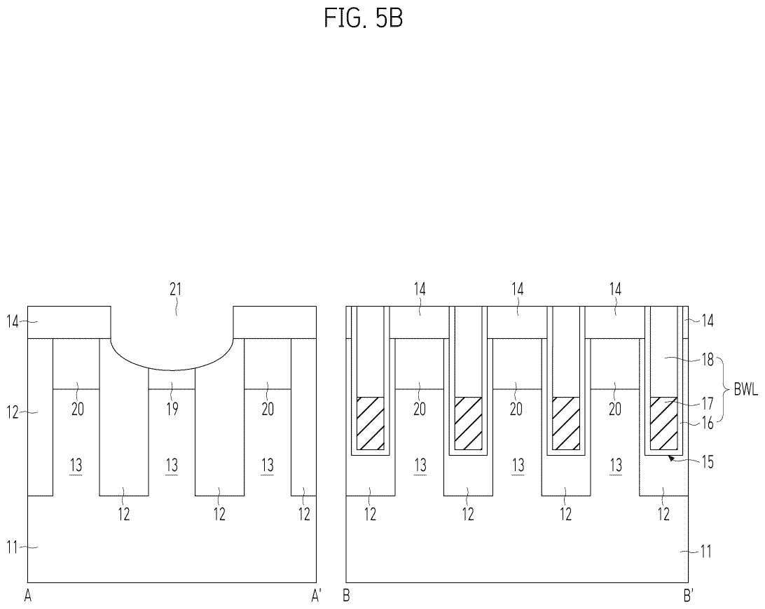

A cell transistor of a memory cell may be formed by the buried word line 17 and the first and second impurity regions 19 and 20. Referring to FIGS. 5A and 5B, a bit line contact hole 21 may

be formed. To form the bit line contact hole 21, the hard mask layer 14 may be etched by using a contact mask. The bit line contact hole 21 may have a circular shape or an elliptical shape from the perspective of a plan view. A portion of the substrate 11 may be exposed by the bit line contact hole 21. The bit line contact hole 21 may have a diameter that is controlled to a predetermined line width. The bit line contact hole 21 may be formed to expose a portion of the active region 13. For example, the first impurity region 19 may be exposed by the bit line contact hole 21. The bit line contact hole 21 may have a diameter which is greater than the width of the short axis of the active region 13. Therefore, in the etching process for forming the bit line contact hole 21, the first impurity region 19, the isolation layer 12, and a portion of the gate capping layer 18 may be etched. The gate capping layer 18, the first impurity region 19, and the isolation layer 12 below the bit line contact hole 21 may be recessed to a predetermined depth. Accordingly, the bottom portion of the bit line contact hole 21 may extend into the substrate 11. As the bit line contact hole 21 extends, the surface of the first impurity region 19 may be recessed. The surface of the first impurity region 19 may be lower than the surface of the active region 13.

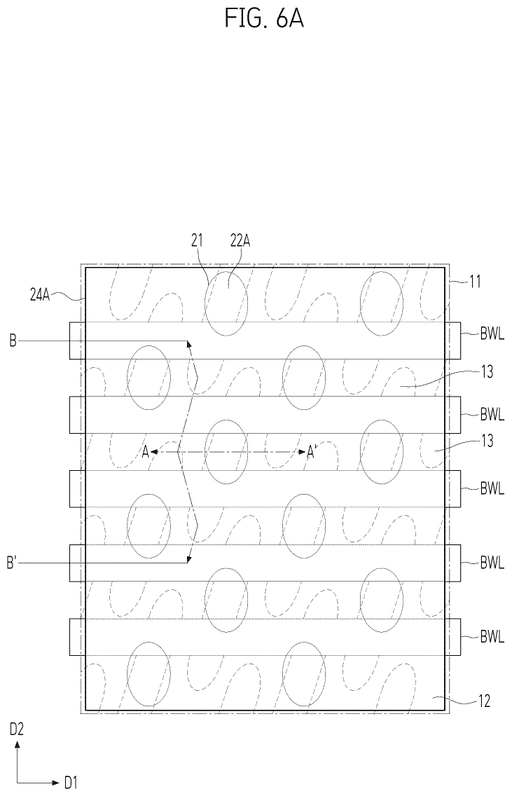

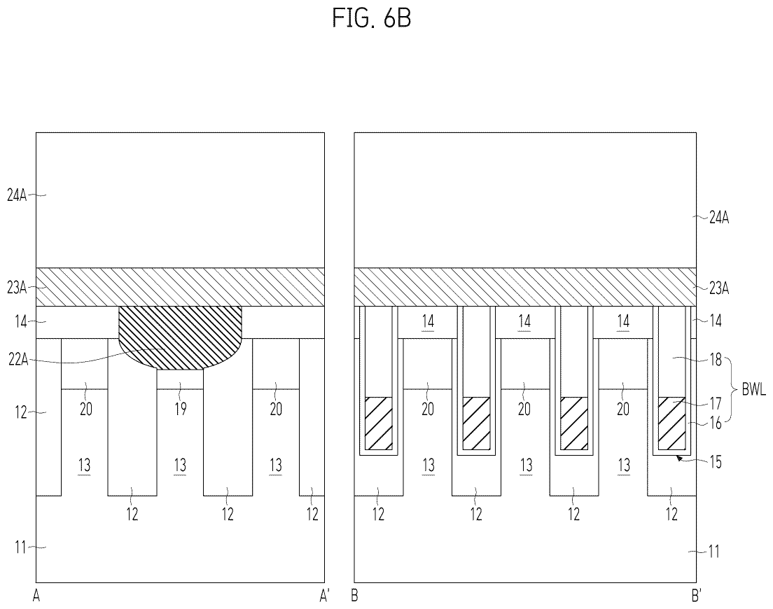

Referring to FIGS. 6A and 6B, a pre-plug 22A may be formed. The pre-plug 22A may be formed by a selective epitaxial growth (SEG) process. For example, the pre-plug 22A may include a phosphorus-doped epitaxial layer, for example, SEG SiP. In this way, the pre-plug 22A may be formed by the selective epitaxial growth process without voids. According to another embodiment of the present invention, the pre-plug 22A may be formed by a process of depositing a polysilicon layer and a Chemical-Mechanical Polishing (CMP) process. The pre-plug 22A may fill the bit line contact hole 21. The top surface of the pre-plug 22A may be disposed at the same level as the top surface of the hard mask layer 14.

A bit line conductive layer 23A and a bit line hard mask layer 24A may be stacked over the pre-plug 22A. The bit line conductive layer 23A and the bit line hard mask layer 24A may be sequentially stacked over the pre-plug 22A and the hard mask layer 14. The bit line conductive layer 23A may include a metal-containing material. The bit line conductive layer 23A may include a metal, a metal nitride, a metal silicide, or a combination thereof. According to an embodiment of the present invention, the bit line conductive layer 23A may include tungsten (W). According to another embodiment of the present invention, the bit line conductive layer 23A may include a stack of titanium nitride and tungsten (TiN/W). In this case, the titanium nitride may serve as a barrier. The bit line hard mask layer 24A may be formed of a dielectric material having an etching selectivity with respect to the bit line conductive layer 23A and the pre-plug 22A. The bit line hard mask layer 24A may include silicon oxide or silicon nitride. According to an embodiment of the present invention, the bit line hard mask layer 24A may be formed of silicon nitride.

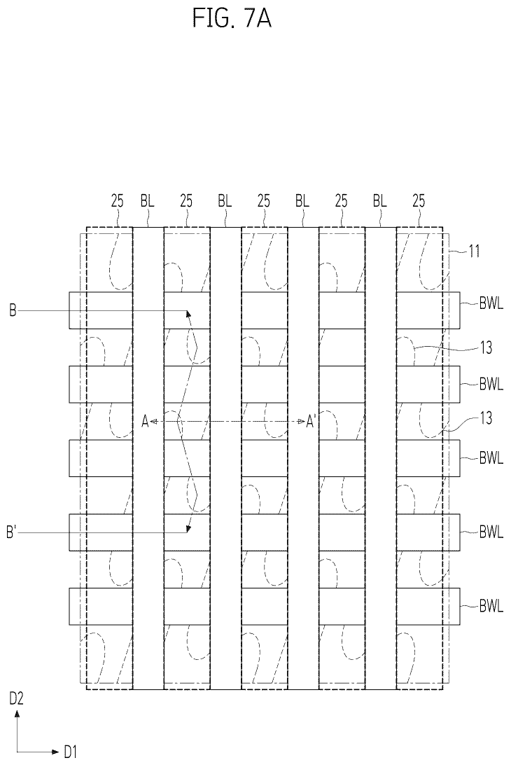

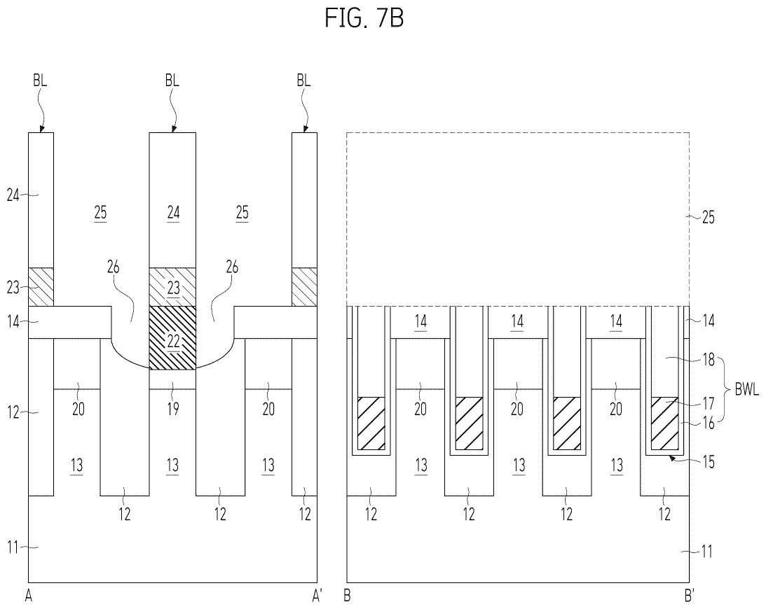

Referring to FIGS. 7A and 7B, a line structure including a first conductive pattern, i.e., a bit line structure BL, may be formed. The bit line structure BL may include a stack of a bit line contact plug 22, a bit line 23, and a bit line hard mask 24. The bit line contact plug 22, the bit line 23, and the bit line hard mask 24 may be formed by an etching process using a bit line mask layer. In the bit line structure BL, the first conductive pattern may include the bit line 23.

The bit line hard mask layer 24A and the bit line conductive layer 23A of FIG. 6B may be etched by using the bit line mask layer as an etching barrier. As a result, the bit line 23 and the bit line hard mask 24 may be formed. The bit line 23 may be formed by etching the bit line conductive layer 23A. The bit line hard mask 24 may be formed by etching the bit line hard mask layer 24A.

Subsequently, the pre-plug 22A of FIG. 6B may be etched with the same line width as that of the bit line 23. As a result, the bit line contact plug 22 may be formed. The bit line contact plug 22 may be formed over the first impurity region 19. The bit line contact plug 22 may be coupled between the first impurity region 19 and the bit line 23. The bit line contact plug 22 may be formed in the bit line contact hole 21. The line width of the bit line contact plug 22 may be less than the diameter of the bit line contact hole 21. Accordingly, gaps 26 may be defined on both sides of the bit line contact plug 22.

As described above, the gaps 26 may be formed in the bit line contact hole 21 by forming the bit line contact plug 22. This is because the bit line contact plug 22 is formed by being etched to be less than the diameter of the bit line contact hole 21. The gaps 26 may be formed not in a surrounding shape that surrounds the bit line contact plug 22, but may be formed independently on both side walls of the bit line contact plug 22. As a result, one bit line contact plug 22 and a pair of gaps 26 may be disposed in the bit line contact hole 21, and the pair of gaps 26 may be separated by the bit line contact plug 22. The bottom surface of the gap 26 may extend into the inside of the isolation layer 12. The bottom surface of the gap 26 may be disposed at a lower level than the recessed top surface of the first impurity region 19. According to another embodiment of the present invention, from the perspective of a top view, the gaps 26 may have a surrounding shape that surrounds the bit line contact plug 22.

A structure including the bit line contact plug 22, the bit line 23, and the bit line hard mask 24 that are stacked in the mentioned order may be referred to as a bit line structure BL. From the perspective of a top view, the bit line structure BL may be a line-shaped pattern structure extending in the second direction D2.

A line-shaped opening 25 may be defined between the neighboring bit line structures BL. The line-shaped opening 25 may be parallel to the bit line structures BL. The hard mask layer 14 and the gap 26 may be exposed by the line-shaped opening 25.

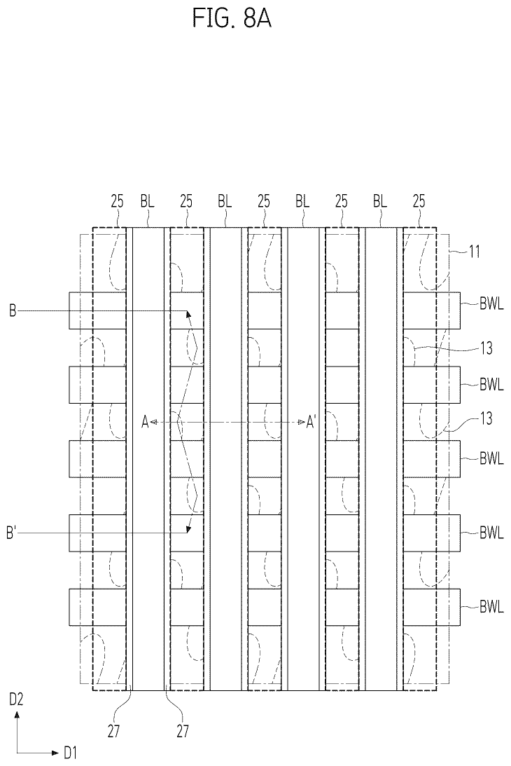

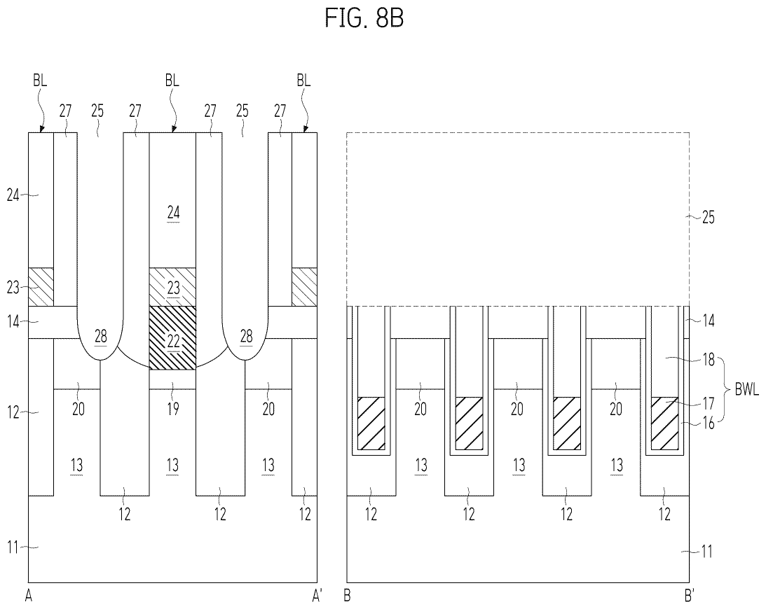

Referring to FIG. 8A and FIG. 8B, a spacer 27 may be formed on both side walls of the bit line structure BL.

Forming the spacer 27 may include forming a spacer layer over the bit line structures BL and etching the spacer layer. The spacer layer may cover both side walls of the bit line contact plug 22 and both side walls of the bit line 23. The spacer layer may also cover both side walls and the top surface of the bit line hard mask 24. The spacer layer may include a dielectric material. To form the spacer 27, the spacer layer may be selectively etched. The spacer 27 may be formed on the side walls of the line-shaped opening 25.

The spacer 27 may include silicon nitride, silicon oxide, a low-k material, or a combination thereof. The low-k material may include SiBN, SiCO, SiCN, SiBCN, or a combination thereof. According to another embodiment of the present invention, the spacer 27 may include a multi-layer spacer. For example, the spacer 27 may include NKON, NKNAN, NKOK, NKOKN, NKAKN, KOK, or KAK, where N refers to silicon nitride, and K refers to a low-k material, and O refers to silicon oxide, and A refers to an air gap. According to another embodiment of the present invention, the outermost spacer of the spacer 27 may include a low-k material.

Subsequently, the underlying materials may be etched to be self-aligned to the spacer 27. Accordingly, a plurality of recessed regions 28 exposing a portion of the active region 13 may be formed between the bit line structures BL. An anisotropic etching process or a combination of an anisotropic etching process and an isotropic etching process may be performed to form the recessed regions 28. For example, an anisotropic etching process may be performed to form the spacer 27 between bit line structures BL, and then a portion of the exposed active region 13 may be isotropically etched. According to another embodiment of the present invention, the hard mask layer 14 may also be isotropically etched. Portions of the active region 13 may be exposed by the recessed regions 28.

The recessed regions 28 may extend into the substrate 11. While the recessed regions 28 is formed, the isolation layer 12, the gate capping layer 18, and the second impurity region 20 may be recessed to a predetermined depth. The bottom surface of the recessed regions 28 may be disposed at a lower level than the top surface of the bit line contact plug 22. The bottom surface of the recessed regions 28 may be disposed at a higher level than the bottom surface of the bit line contact plug 22. The line-shaped openings 25 and the recessed regions 28 may be coupled to each other. The vertical structure of the line-shaped openings 25 and the recessed regions 28 may be referred to as a ‘storage contact hole’.

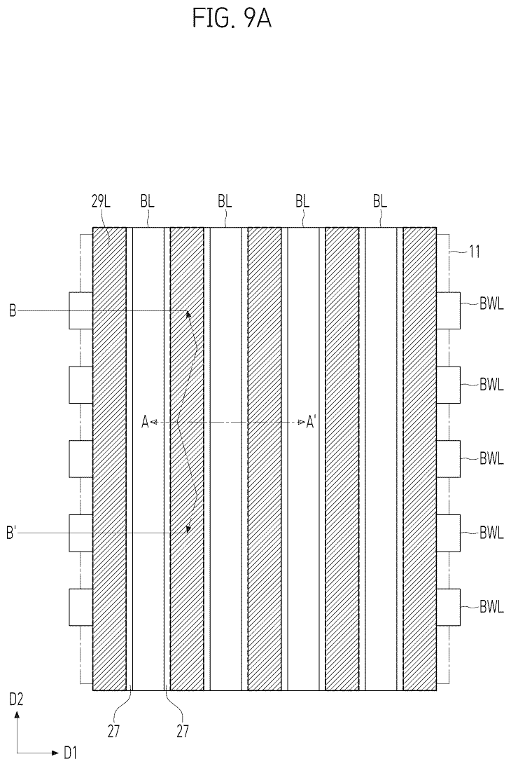

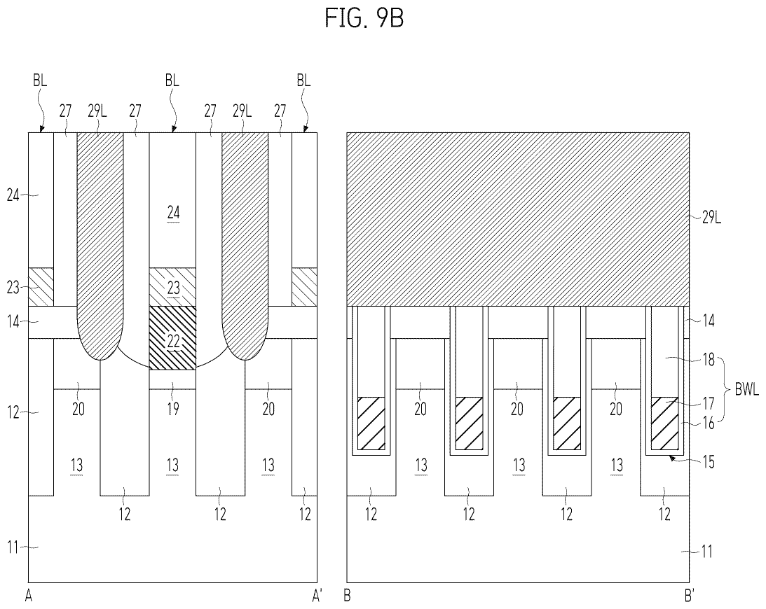

Referring to FIGS. 9A and 9B, line patterns 29L may be formed to respectively fill the line-shaped openings 25 of FIG. 8B. The line patterns 29L may fill the line-shaped openings 25 and the recessed regions 28. The line patterns 29L may contact the second impurity regions 20. The line patterns 29L may be adjacent to the bit line structures BL. From the perspective of a top view, a plurality of line patterns 29L may be disposed between a plurality of bit line structures BL. The plurality of line patterns 29L may include a semiconductor material, for example, doped polysilicon. The plurality of line patterns 29L may extend in the second direction D2.

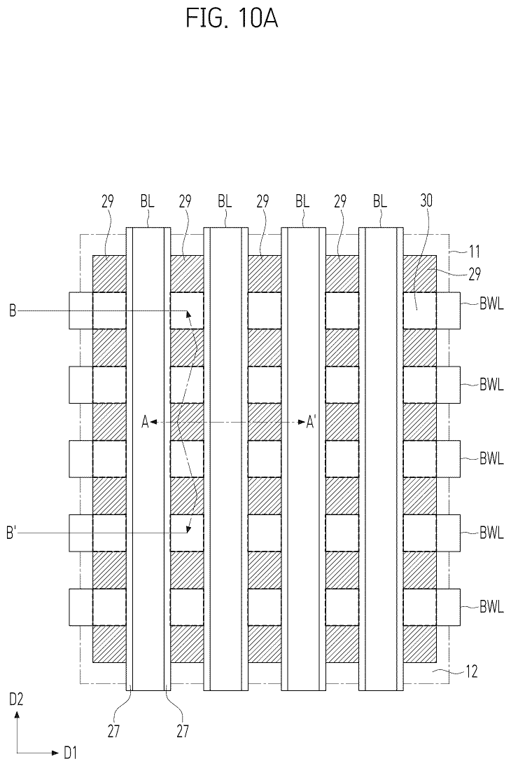

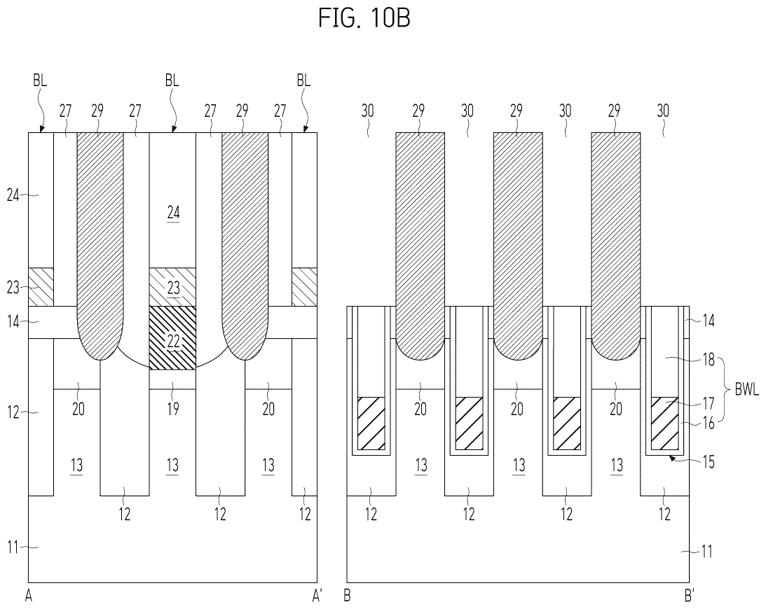

Referring to FIGS. 10A and 10B, the line patterns 29L may be etched by using a mask layer extending in a direction intersecting with the line patterns 29L. Accordingly, a plurality of contact plugs 29 and a plurality of isolation openings 30 may be formed. From the perspective of a top view, the plurality of contact plugs 29 may be disposed between the neighboring bit line structures BL, and each isolation opening 30 may be disposed between two adjacent contact plugs 29. The contact plugs 29 may be a second conductive pattern, and the contact plugs 29 may be referred to as a second conductive pattern structure. The isolation openings 30 may be referred to as inter-plug openings.

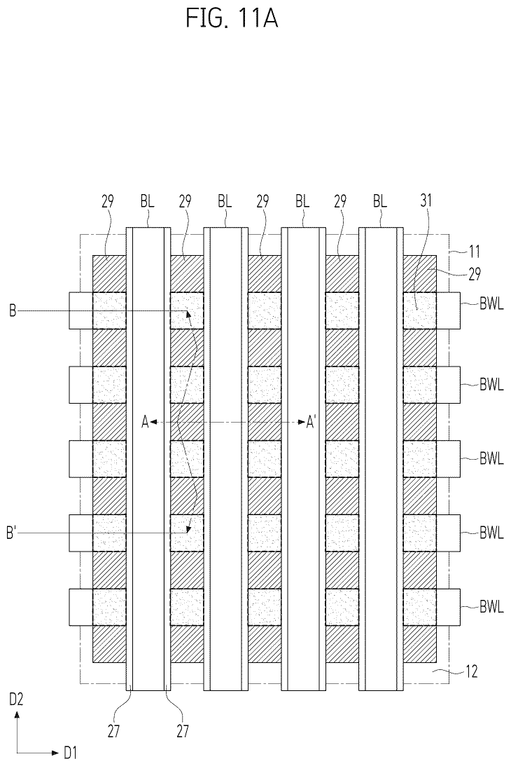

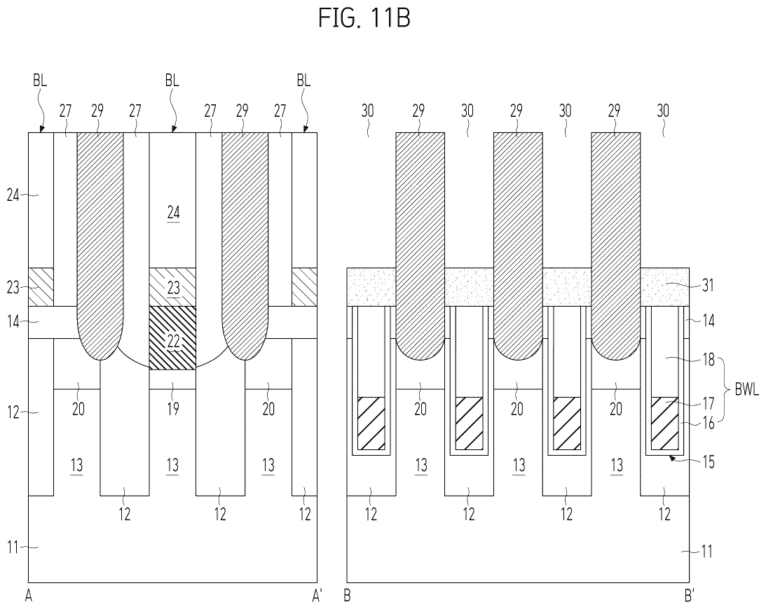

Referring to FIGS. 11A and 11B, a sacrificial layer 31 filling the isolation openings 30 may be formed. To form the sacrificial layer 31, filling a sacrificial material in the isolation openings 30 and etching back the sacrificial material may be included. The sacrificial layer 31 may be a material that may be removed during a subsequent thermal process or an oxygen plasma strip process. The sacrificial layer 31 may include a carbon-containing material or a pyrolytic carbon-containing material. The sacrificial layer 31 may be an air gap target layer, that is, a material that is removed during a subsequent process to form an air gap. The sacrificial layer 31 may also be referred to as an air gap source material.

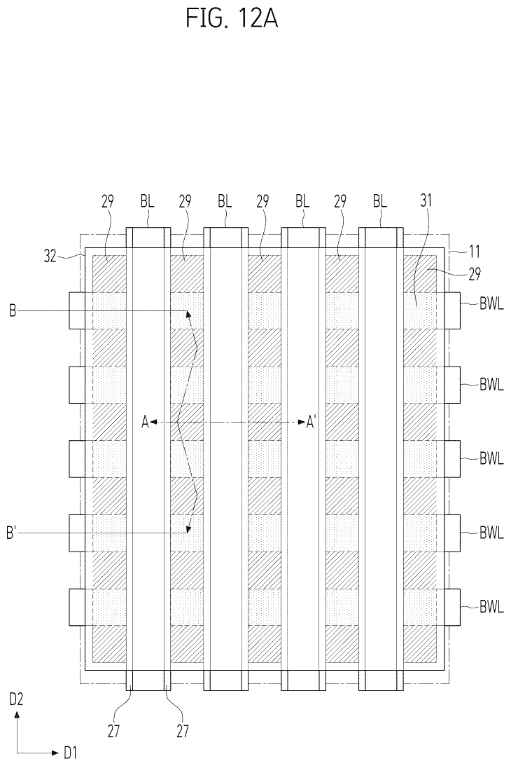

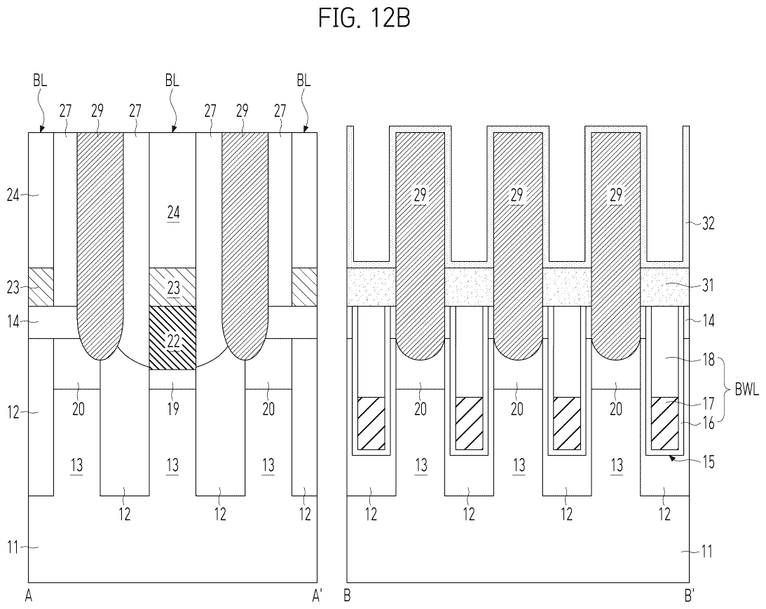

Referring to FIGS. 12A and 12B, a liner layer 32 may be formed over the sacrificial layer 31. The liner layer 32 may be conformally formed over the sacrificial layer 31. The liner layer 32 may include silicon oxide, silicon nitride, or a combination thereof. The liner layer 32 may include silicon nitride deposited in a low-temperature process (i.e., a low-temperature nitride). The liner layer 32 may have a thickness of approximately 50 Å or less.

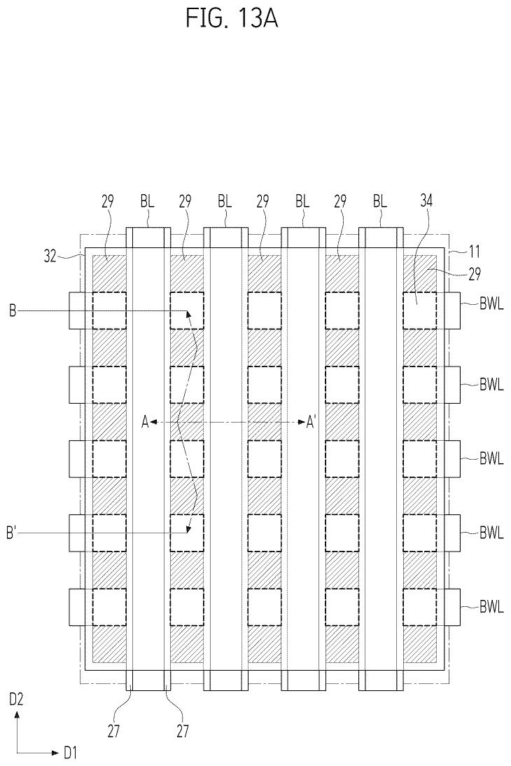

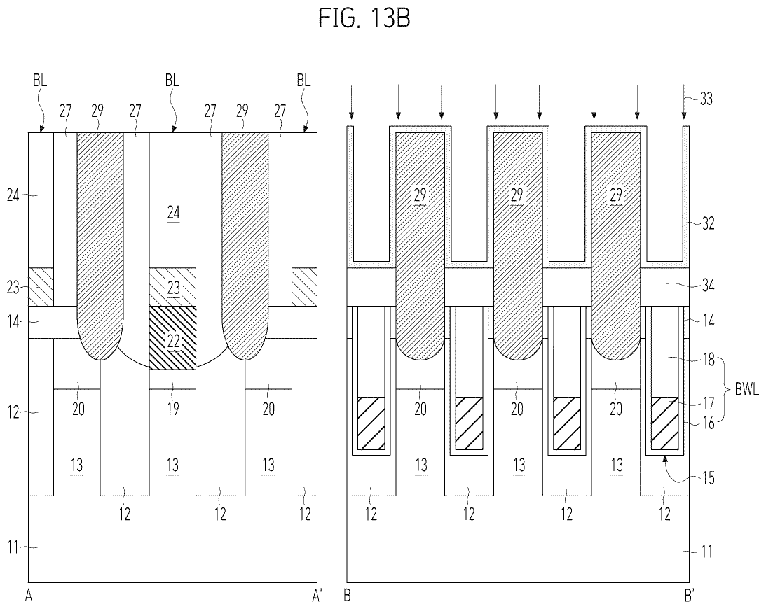

Referring to FIGS. 13A and 13B, the sacrificial layer 31 may be replaced with air gaps 34. A post-processing 33 may be performed to remove the sacrificial layer 31. The post-processing 33 may include a thermal process or an oxygen plasma strip process. The sacrificial layer 31 may be volatilized by the post-processing 33. Accordingly, the air gaps 34 may be formed in the space from which the sacrificial layer 31 is removed. The thermal process may be performed at a temperature for thermally decomposing the sacrificial layer 31. For example, the thermal process may be performed at a temperature of approximately 500° C. The pyrolytic carbon-containing material may be removed by a high-temperature thermal process. The carbon-containing material may be removed by an oxygen plasma strip process. The air gaps 34 may directly expose the lower side walls of the contact plugs 29. As a result, only the air gaps 34 may be disposed between the lower side walls of the contact plugs 29. As a comparative example, when an air gap and a dielectric material are disposed, the parasitic capacitance may increase compared to the case where only the air gaps 34 are disposed. As a comparative example, when the air gaps are embedded during the deposition of a dielectric material, the size of the air gaps may become uneven.

According to an embodiment of the present invention, since the air gaps 34 are formed by volatilizing a pyrolytic material, the position and size of the air gaps 34 may be uniform. Since the air gaps 34 are disposed between the lower side walls of the contact plugs 29, the parasitic capacitance between the lower side walls of the contact plugs 29 may be decreased.

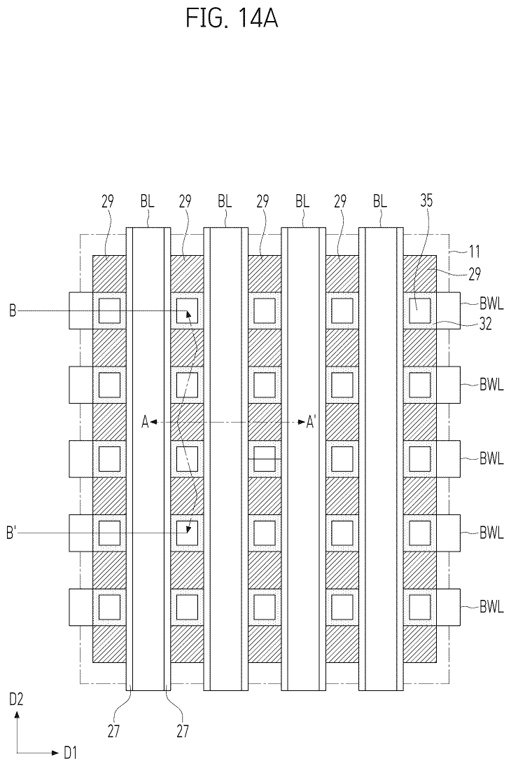

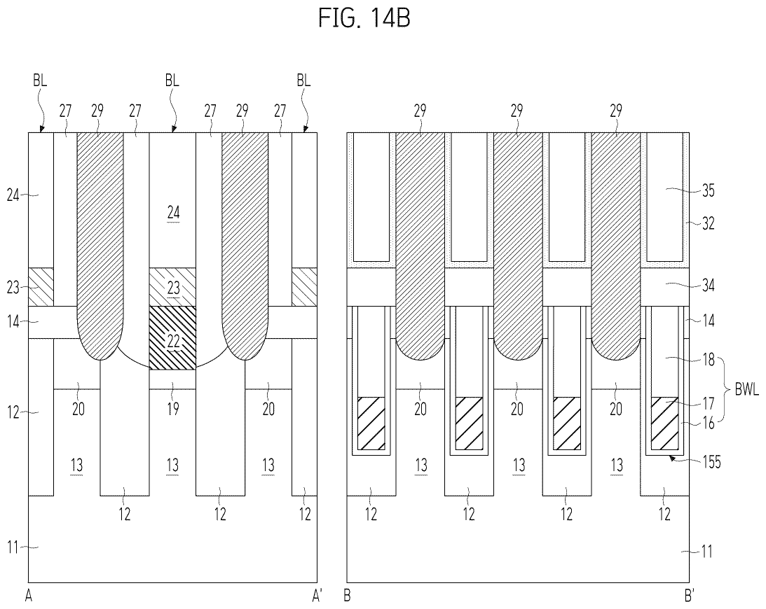

Referring to FIGS. 14A and 14B, a gap-fill layer 35 may be formed over the liner layer 32. The gap-fill layer 35 may include silicon oxide, silicon nitride, or a combination thereof. The combination of the air gaps 34, the liner layer 32, and the gap-fill layer 35 may be referred to as a plug isolation structure or a pattern isolation layer.

In some embodiments, a storage node of a capacitor may be formed over the contact plugs 29 subsequently. According to another embodiment of the present invention, prior to forming the storage node of the capacitor, after the contact plug 29 is etched back, a metal silicide and a metal material may be sequentially formed over the etched-back contact plug 29.

According to the embodiment of the present invention, since the air gaps are formed between the storage contact plugs, leakage current may be decreased.

According to the embodiment of the present invention, since the air gaps are formed between the storage contact plugs, parasitic capacitance between the storage contact plugs may be decreased.

While the present invention has been described with respect to the specific embodiments, it will be apparent to those skilled in the art that various changes and modifications may be made without departing from the spirit and scope of the invention as defined in the following claims. Furthermore, the embodiments may be combined to form additional embodiments.

What is claimed is:

1. A semiconductor device comprising:
a plurality of line structures including a plurality of first conductive patterns over a substrate, respectively;
a plurality of second conductive patterns formed between the line structures, respectively;
a plurality of isolation layers formed between the line structures and the second conductive patterns, respectively; and
a plurality of air gaps disposed at a lower level than the isolation layers to be disposed between the second conductive patterns, respectively.

2. The semiconductor device of claim 1, wherein the air gaps directly contact side walls of the second conductive patterns, respectively.

3. The semiconductor device of claim 1, wherein each of the isolation layers includes:
a liner layer suitable for covering the air gaps; and
a gap-fill layer over the liner layer.

4. The semiconductor device of claim 1, wherein each of the isolation layers include silicon nitride.

5. The semiconductor device of claim 1, wherein each of the first conductive patterns include a bit line, and each of the second conductive patterns include a storage contact plug.

6. The semiconductor device of claim 1, wherein each of the second conductive patterns include doped polysilicon.

7. A method for fabricating a semiconductor device, the method comprising:
forming a plurality of line structures and line-shaped openings between the line structures, over a substrate;
filling the line-shaped openings with conductive line patterns, respectively;
forming a plurality of plugs and a plurality of isolation openings by etching the conductive line patterns;
forming air gap target layers in the isolation openings, respectively;
forming liner layers over the air gap target layers, respectively; and
replacing the air gap target layers with air gaps.

8. The method of claim 7, wherein the air gaps directly contact side walls of the plugs, respectively.

9. The method of claim 7, wherein each of the air gap target layers includes a pyrolytic material.

10. The method of claim 7, wherein the replacing of the air gap target layers with the air gaps includes:
performing a thermal process at a temperature that thermally decomposes each of the air gap target layers.

11. The method of claim 7, wherein each of the air gap target layers includes a carbon-containing material.

12. The method of claim 11, wherein replacing the air gap target layers with the air gaps includes:
performing an oxygen plasma strip process to replace the air gap target layers with each of the air gaps.

13. The method of claim 7, wherein each of the plugs include doped polysilicon.

14. A method for fabricating a semiconductor device, the method comprising:
forming a plurality of bit line structures over a substrate;
forming line-shaped openings between the bit line structures, respectively;
filling the line-shaped openings with conductive line patterns, respectively;
forming a plurality of storage contact plugs and a plurality of isolation openings between the storage contact plugs by etching the conductive line patterns;
filling a pyrolytic material in each of the isolation openings to form air gap target layers;
forming a liner layer over the air gap target layers;
replacing the air gap target layers with air gaps; and
forming a gap-fill layer over the liner layer.

15. The method of claim 12, wherein the air gaps directly contact side walls of the storage contact plugs, respectively.

16. The method of claim 14, wherein replacing the air gap target layers with the air gaps includes
performing a thermal process at a temperature for thermally decomposing the pyrolytic material.

17. The method of claim 14, wherein the pyrolytic material includes a thermally decomposable carbon-containing material.

18. The method of claim 14, wherein each of the storage contact plugs include doped polysilicon.

19. The method of claim 14, further comprising:
forming buried word line structures in the substrate, before forming the bit line structures.
